(19) United States
(12) Patent Application Publication
(10) Pub. No.: US 2026/0156900 A1
(43) Pub. Date: Jun. 4, 2026

(54) METAL-OXIDE-SEMICONDUCTOR FIELD-EFFECT TRANSISTOR WITH DOUBLE SEQUENTIAL TRENCH STRUCTURE

(71) Applicant: Renesas Electronics Corporation, Tokyo (JP)

(72) Inventors: Kijeong HAN, Morrisville, NC (US); Meng Chia LEE, Dallas, TX (US); Dilip Madhav RISBUD, San Jose, CA (US)

(73) Assignee: Renesas Electronics Corporation, Tokyo (JP)

(21) Appl. No.: 18/968,388

(22) Filed: Dec. 4, 2024

(51) Int. Cl. H10D 64/27; H10D 30/66; H10D 62/10; H10D 62/832; H10D 64/01

(52) U.S. Cl. CPC H10D 64/518; H10D 30/668; H10D 62/107; H10D 64/027; H10D 62/8325

(57) ABSTRACT

A semiconductor structure includes a silicon carbide semiconductor substrate of a first conductivity type. The semiconductor structure further includes a drift layer of the first conductivity type located above the semiconductor substrate, a channel layer of a second conductivity type, opposite to the first conductivity type, located above the drift layer, and a source region of the first conductivity type located above the channel layer. The semiconductor structure further includes a stepped shaped trench structure that extends through the source region and the channel layer until a top portion of the drift layer, a gate electrode located within the trench structure and surrounded by a gate insulating film, and a shield region of the second conductivity type covering a bottom of the trench structure such that the shield region extends laterally along the trench structure to a trench corner.

### BACKGROUND

The present disclosure generally relates to the field of semiconductor devices, and more particularly to trench metal-oxide-semiconductor field-effect transistors (MOSFETs) and their associated shielding techniques.

Trench MOSFETs are widely used in power electronics due to their high efficiency and performance characteristics. These devices are designed to handle high voltages and currents with reduced on-resistance compared to conventional planar MOSFETs. Trench MOSFETs incorporate a vertical structure where the gate electrode is placed within a trench etched into the semiconductor substrate, providing a compact and efficient layout.

Despite their advantages, trench MOSFETs face challenges related to device performance and reliability, particularly in high-density integrated circuits. One critical issue is the management of parasitic capacitances and electric fields that can negatively impact the device's switching performance and overall efficiency.

### SUMMARY

According to an embodiment of the present disclosure, a semiconductor structure includes a semiconductor substrate of a first conductivity type, the semiconductor structure including silicon carbide. The semiconductor structure further includes a drift layer of the first conductivity type located above the semiconductor substrate, a channel layer of a second conductivity type opposite to the first conductivity type located above the drift layer, and a source region of the first conductivity type located above the channel layer. The semiconductor structure further includes a trench structure extending through the source region and the channel layer until a top portion of the drift layer, a gate electrode located within the trench structure, the gate electrode being surrounded by a gate insulating film, and a shield region of the second conductivity type covering a bottom of the trench structure such that the shield region extends laterally along the trench structure to a trench corner, the bottom of the trench structure having a stepped shape.

According to another embodiment of the present disclosure, a semiconductor structure includes a drift region disposed above an upper surface of a semiconductor substrate, the drift region and the semiconductor substrate including a first conductivity type. The semiconductor structure further includes a trench structure within the drift region, the trench structure being adjacent to a JFET region located above the drift region, a channel region located above the JFET region, and a first doped region located above the channel region. The trench structure further includes a bottom region featuring a bottom section having a first inclination angle relative to a first direction, a sloped section having a second inclination angle relative to the first direction, and an upper section having a third inclination angle relative to the first direction. The semiconductor structure further includes a shield region of a second conductivity type disposed on the bottom region of the trench structure, the shield region extending laterally along the trench structure to a trench corner.

According to yet another embodiment of the present disclosure, a semiconductor structure includes a drift region located above an upper surface of a semiconductor substrate, the drift region and the semiconductor substrate including a first conductivity type. The semiconductor structure further includes a first trench structure within the drift region, the first trench structure including a horizontal profile and a second trench structure within the drift region adjacent to the first trench structure, the second trench structure including a tilted profile, the first trench structure and the second trench structure include a double sequential trench structure. The semiconductor structure further includes a shield region of a second conductivity type, the shield region extends laterally along the double sequential trench structure to a trench corner, with a width of the shield region being at least equal to a width of a widest portion of the double sequential trench structure.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a side view of a semiconductor structure depicting an example of a portion of a double sequential trench SiC MOSFET, according to an embodiment of the present disclosure;

FIG. 2 is a cross-sectional view of the semiconductor structure depicting one cell of semiconductor structure that implements the double sequential trench SiC MOSFET, according to an embodiment of the present disclosure;

FIG. 3 is an example of a double sequential trench structure, according to an embodiment of the present disclosure;

FIG. 4A is a side view of the semiconductor structure depicting forming a first trench structure, according to an embodiment of the present disclosure;

FIG. 4B is a side view of the semiconductor structure depicting forming a first layer of oxide, according to an embodiment of the present disclosure;

FIG. 4C is a side view of the semiconductor structure depicting removing a portion of the first layer of oxide, according to an embodiment of the present disclosure;

FIG. 4D is a side view of the semiconductor structure depicting forming a second trench structure, according to an embodiment of the present disclosure;

FIG. 4E is a side view of the semiconductor structure depicting forming a third doped region, according to an embodiment of the present disclosure;

FIG. 4F is a side view of the semiconductor structure depicting forming an oxide region and a gate region, according to an embodiment of the present disclosure;

FIG. 5 is a side view of a semiconductor structure depicting another example of a portion of a double sequential trench SiC MOSFET; and

FIG. 6 is a flowchart outlining operational steps for the fabrication of a semiconductor structure having a double sequential trench structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In SiC trench MOSFETs, the reliability of the gate oxide layer presents a critical challenge. Specifically, during the off-state operation, high electric fields tend to concentrate at the bottom corners of the trench, which can lead to accelerated oxide degradation and device failure. This phenomenon is particularly noticeable in conventional trench MOSFET designs, where the oxide can be left vulnerable to these elevated electric fields.

To mitigate this issue, a P-type implant, referred to as P-shield, is formed beneath the trench. The effectiveness of the P-shield is contingent upon its proximity to the trench corners; closer positioning to the trench corners enhances the robustness of the device against high electric fields. However, to ensure precise alignment and maximize the protective benefits of the P-shield, it is necessary that the implant is performed after the trench etching process.

Current methodologies demonstrate limitations in the implementation of the P-shield implant. For instance, when the implant is performed in a horizontal or flat single-trench structure, the P-shield implant occurs straight downward which causes the trench corners to remain exposed to significant electric fields. Conversely, when the implant is performed in a tilted or angled single-trench structure, the P-shield implant can spread laterally somewhat alleviating this issue; however, it does not entirely eliminate vulnerability at the trench corners.

Embodiments of the present disclosure provide a SiC trench MOSFET in which the aforementioned approaches are combined in a double sequential trench structure that causes the P-shield implant to extend further in a lateral direction, significantly reducing the electric field concentration at the trench corners, which results in improved device performance. The P-shield implant in the double sequential trench structure effectively suppresses the high oxide electric field by spreading laterally instead of downward into the substrate, increasing the doping concentration near the trench corner. This self-aligned implant avoids misalignment issues common in regular trench structures, where the P bottom implant can negatively impact channel surface doping concentration. To mitigate this, thicker spacers are typically required, but in the proposed double sequential trench structure, the trench tilted angle allows for sufficient lateral spread, maintaining proximity to the trench corner. The proposed embodiments can effectively reduce the electric field around the trench bottom and corner, which facilitates electric field sharing between the trench corner and P shield region. Additionally, this configuration is expected to lower gate-to-drain capacitance (Cgd) due to the wider depletion region resulting from the higher doping concentration of the P-shield implant.

In the proposed embodiments, the double sequential trench structure is achieved through a two-step process: (1) the formation of a first trench structure using various etching techniques to create a horizontal or flat trench configuration, followed by (2) a tilted or angled etching process to create a second trench structure with an angled configuration. In some embodiments, the second trench can also be formed with a flat configuration. Regardless of whether the second trench is tilted or flat, a similar resurf effect is anticipated due to the concentration of the electric field at the P-shield peak doping and the trench corner. This effect can lead to a reduction in the maximum oxide electric field compared to a single trench structure. In the proposed double sequential trench configuration, the current flow is unaffected by the P-shield, suggesting an improvement in the on-state resistance per unit area Ron,sp.

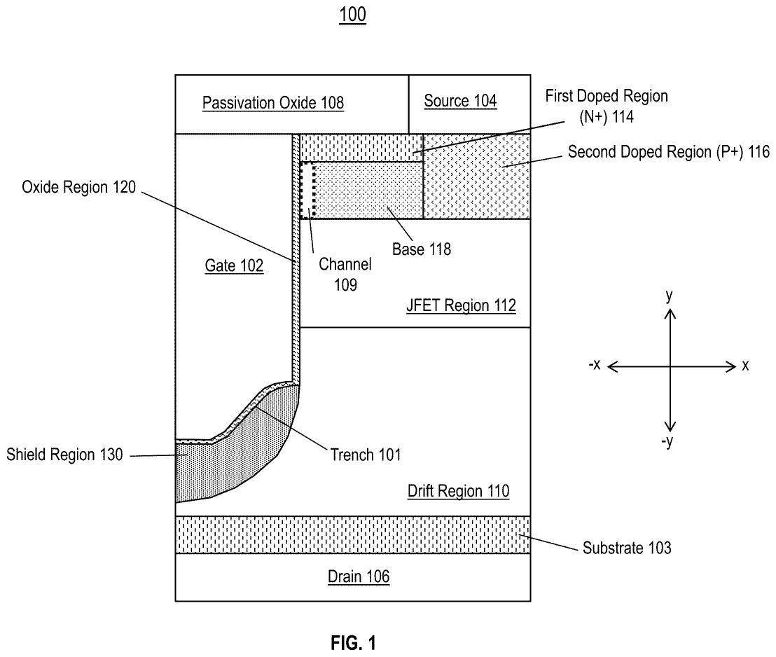

Embodiments by which the double sequential trench SiC MOSFET can be formed is described in detail below by referring to the accompanying drawings in FIGS. 1-6.

FIG. 1 depicts a side view of a semiconductor structure 100, according to an embodiment of the present disclosure. Specifically, in this embodiment, FIG. 1 depicts an example of a portion of a double sequential trench SiC MOSFET.

The semiconductor structure 100 can be formed using a substrate 103 that includes a gate region (or gate electrode, hereinafter “gate”) 102, a source terminal (hereinafter “source”) 104, a drain terminal (hereinafter “drain”) 106, a layer of passivation oxide 108, a drift region 110, a junction field effect transistor (JFET) region 112, a first doped region 114, a second doped region 116, a base 118, an oxide region 120 and a third doped region (hereinafter “shield region”) 130. Substrate 103 can be a semiconductor substrate that is doped with impurities of a first type, such as N-type impurities, such that substrate 103 is of a first conductivity type. In the descriptions herein, the first conductivity type can be either N-type or P-type and a second conductivity type can have opposite conductivity from the first conductivity type. For example, when the first conductivity type is N-type, second conductivity type is P-type, and vice versa.

In an embodiment, semiconductor structure 100 can be one SiC trench MOSFET among a plurality of SiC trench MOSFETs in an integrated circuit. In general, trench MOSFETs can be formed by etching a trench structure 101 vertically (e.g., in the −y direction) into a SiC substrate (e.g., substrate 103) and doping the remaining SiC substrate with impurities of different types and/or concentrations. Walls of the trench structure 101 can be lined with a layer of gate oxide (e.g., oxide region 120, which will be further described below), and the lined trench structure 101 can be filled with a conductive material, such as polysilicon, forming the gate 102. Source 104 can be a region of the first conductivity type and drain 106 can be a region of the first conductivity type. Passivation oxide 108 can be a layer of oxide that is deliberately formed to function as a barrier to protect semiconductor structure 100 from environmental factors such as moisture, chemicals, and environmental pollutants that could compromise functionality of semiconductor structure 100.

Drift region 110 can be located between base 118 and substrate 103, and can extend along the walls of the trench structure 101 where gate 102 is located. Drift region 110 can be a region where carriers (e.g., electrons or holes) can drift from the source 104 to the drain 106. The electric field can direct the carriers to move towards the drain 106, thus allowing current to flow from source 104 to drain 106. The strength and distribution of the electric field in drift region 110 can impact various electrical characteristics, such as on-resistance (RDSon), breakdown voltage, or other characteristics of semiconductor structure 100.

In one or more embodiments, when a voltage is applied to the gate 102, an electric field is generated to form an inversion layer in a channel region (hereinafter “channel”) 109 of the second conductivity type. Channel 109 is located within a portion of base 118 adjacent to gate 102. Channel 109 is established within the semiconductor structure 100 during its operational phase. In an embodiment, channel 109 can be of the second conductivity type and have a dopant concentration varying between approximately 1×10¹⁵ cm⁻³ and 1×10¹⁸ cm⁻³. In some embodiments, impurities of the first type can be used to form channel 109, enabling N-channel depletion mode MOSFET operations.

Semiconductor structure 100 can further include JFET region 112 formed within drift region 110 that provides a direct junction between the gate 102 and the channel 109. In an embodiment, the JFET region 112 can be located between a top surface of drift region 110, adjacent to trench 101, and bottom surfaces of channel 109, base 118 and second doped region 116. In some instances, JFET region 112 can be formed with a higher donor doping of the first conductivity type that can vary between, for example, 1×10¹⁶ cm⁻³ and 1×10¹⁸ cm⁻³.

First doped region 114 can be a region that is doped with impurities of a first type, such as N-type impurities. Second doped region 116 can be a region that is doped with impurities of a second type, such as P-type impurities. First doped region 114 can have the first conductivity type and second doped region 116 can have the second conductivity type. First doped region 114 and second doped region 116 can be in contact with source 104. First doped region 114 can be in contact with passivation oxide 108. The first doped region 114 functions as a source region of the semiconductor structure 100. The second doped region includes a heavily doped semiconductor region.

When the first conductivity type is N-type, then first doped region 114 can be created by, for example, ion implantation or diffusion where N-type dopants such as Phosphorus (P) or Arsenic (As) are implanted into the region that eventually become first doped region 114. If the first conductivity type is N-type, then second doped region 116 can be created by, for example, ion implantation or diffusion where P-type dopants such as Boron (B), Aluminum (Al) or Gallium (Ga) are implanted into the region that eventually become second doped region 114. The depth and doping concentration of first doped region 114 and the second doped region 116 can be controlled to define the RDSon and breakdown voltage of semiconductor structure 100. For example, a doping concentration of the first dope region 114 can be of approximately 1×10¹⁹ cm⁻³ to approximately 1×10²¹ cm⁻³, while a doping concentration of second doped region 116 can be of approximately 1×10¹⁸ cm⁻³ to approximately 1×10²¹ cm⁻³.

Base 118 can be doped with impurities of the second type (e.g., same as second doped region 116), such as P-type impurities. The impurity concentration of impurities being used for doping base 118 can be less than the impurity concentration of second doped region 116. By having smaller impurity concentration than second doped region 116, base 118 can facilitate majority carriers injected from the source 104 to traverse the base 118 and reach the drain 106. In an embodiment, a doping concentration of the base 118 can vary between approximately 1×10¹⁶ cm⁻³ to approximately 1×10¹⁸ cm⁻³. In some embodiments, base 118 can be lightly doped with impurities of the first type to achieve an accumulation-mode MOSFET (ACCUFET), in such cases the doping concentration of base 118 can vary between approximately 1×10¹⁴ cm⁻³ to approximately 1×10¹⁶ cm⁻³. In other embodiments, base 118 can be doped with impurities of the first type to achieve a depletion-mode MOSFET, in such cases the doping concentration of base 118 can vary between approximately 1×10¹⁶ cm⁻³ to approximately 1×10¹⁸ cm⁻³.

In an aspect, the layer of oxide layer lining the trench structure 101, or gate oxide, can be an insulating material that separates the gate 102 from the semiconductor channel (e.g., channel 109) and other conductive layers or regions of semiconductor structure 100. The insulating material lining trench structure 101 can be, for example, Silicon Dioxide (SiO₂) or other high-k dielectrics. The layer of oxide can also help to control the flow of current between source 104 and drain 106 by modulating the electric field in drift region 110.

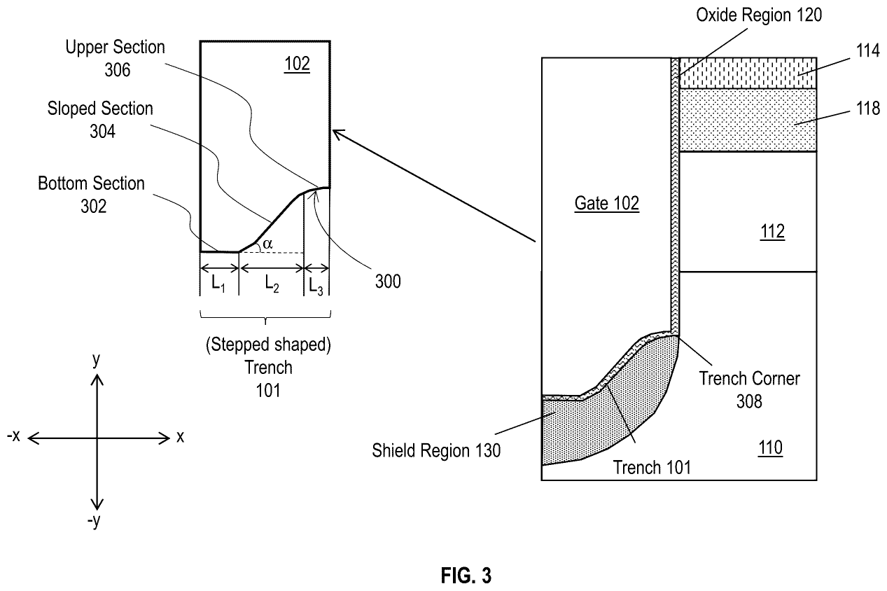

When the electric field in drift region 110 is too high, the gate oxide can degrade over time and negatively impact the overall lifespan and reliability of semiconductor structure 100. The oxide degradation can lead to shifts in the threshold voltage. For trench MOSFETs, the trench tends to have a relatively deeper profile (e.g., along the y-axis) compared to its width (e.g., x-axis). Thus, the electric field lines tend to concentrate at the bottom of the trench causing the electric field underneath the trench (e.g., −y direction) to be higher than other regions, such as near the sidewalls of the trench. In some conventional devices, to mitigate the high electric field at the bottom of the trench, a P-shield, which is a P-type implant, can be positioned underneath the trench to mitigate the high electric field underneath the trench. In the embodiment depicted in FIG. 1, the double sequential trench configuration of trench structure 101 enables the P-shield implant (e.g., shield region 130) to extend further laterally, allowing the high doping P-shield implant to approach the trench corners (e.g., trench corner 308 shown in FIG. 3) more closely. This design significantly reduces electric field concentration at the trench corners, leading to improved device performance. The detailed process for forming the double sequential trench structure 101 will be described in detail below.

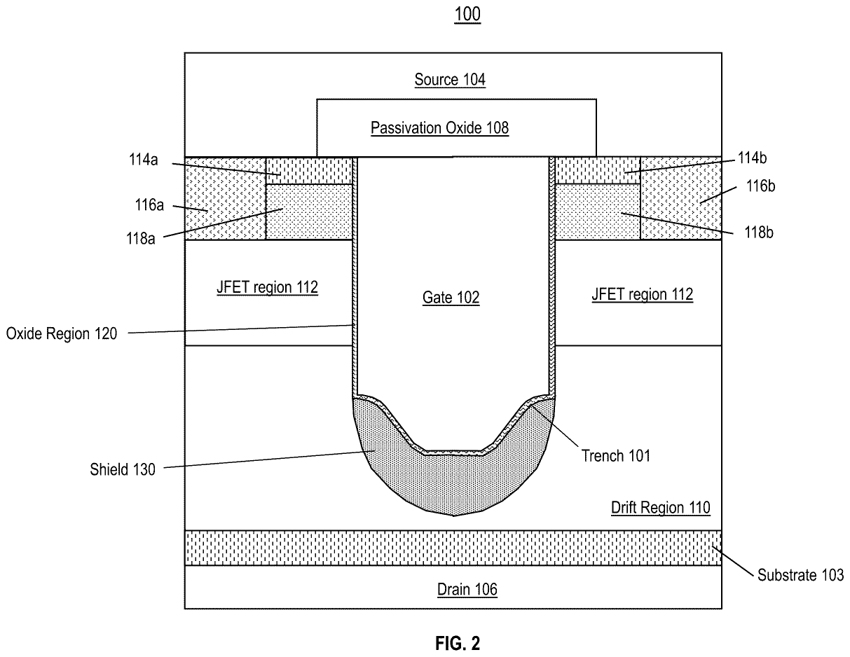

FIG. 2 is a cross-sectional view of the semiconductor structure 100, according to an embodiment of the present disclosure. Specifically, FIG. 2 shows a cross-sectional view of one whole unit, or one cell, of semiconductor structure 100 that implements a double sequential trench SiC MOSFET. Descriptions of FIG. 2 can reference components shown in FIG. 1.

As shown in FIG. 2, trench structure 101 is etched and formed between two first doped region regions 114a, 114b (e.g., first doped region), two second doped region regions 116a, 116b (e.g., second doped region) and two base regions 118a, 118b. Trench structure 101, in its entirety as shown in FIG. 2, features a bottom region consisting of two laterally tilted sections flanking a flat or horizontal middle section. Shield region 130 can span across the bottom portion of the trench structure 101 without extending past the sidewalls of trench structure 101. The oxide region 120 substantially covers the bottom portion of trench structure 101.

FIG. 3 illustrates an example of a double sequential trench structure or trench structure 101. Description of FIG. 3 can reference components shown in FIG. 1 and FIG. 2. As shown in FIG. 3, a bottom region 300 of trench structure 101 can include a bottom section 302, a sloped section 304, and an upper section 306. In this embodiment, a first length of the bottom section 302 is labeled L₁, a second length of the slopped section 304 is labeled L₂, and a third length of the upper section 306 is labeled L₃. For example, the first length L₁ can vary between approximately 1 nm and approximately 0.2 μm, the second length L₂, can vary between approximately 1 nm and approximately 0.2 μm, and the third length L₃ can vary between approximately 1 nm and approximately 0.2 μm. In one or more embodiments, a distance between the upper section 306 and the bottom section 302 can be approximately more than 1 nm and less than 0.2 μm.

In this embodiment, both the bottom section 302 and the upper section 306 feature a substantially flat or horizontal configuration, meaning that their inclination angle relative to the horizontal (x-direction) is approximately 0 degrees, while the sloped section 304 includes an inclination angle α relative to the horizontal (x-direction) that can vary between approximately 0° and approximately 45°. As illustrated in FIG. 3, trench structure 101 exhibits a stepped shape due to the varying inclination angles of the bottom section 302, sloped section 304, and upper section 306.

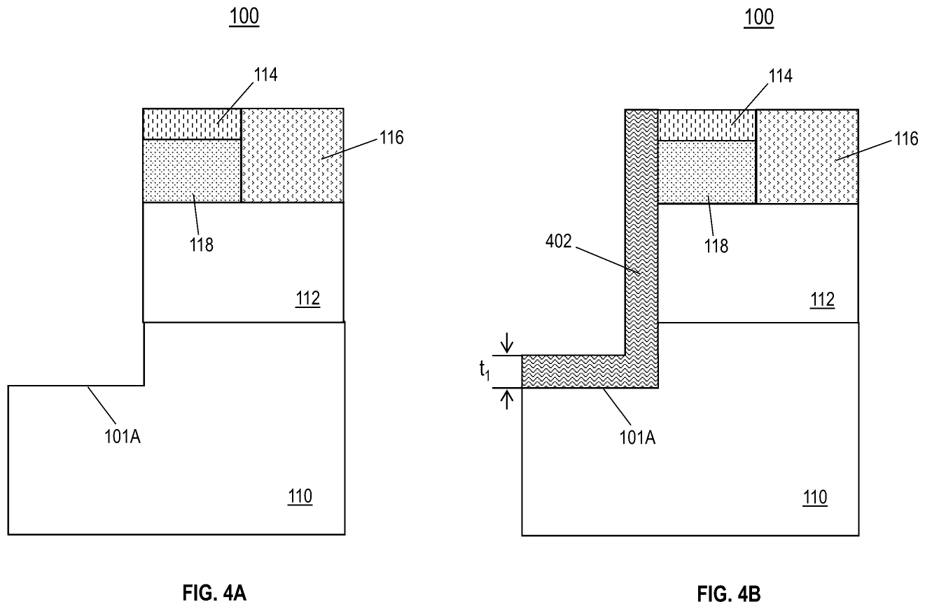

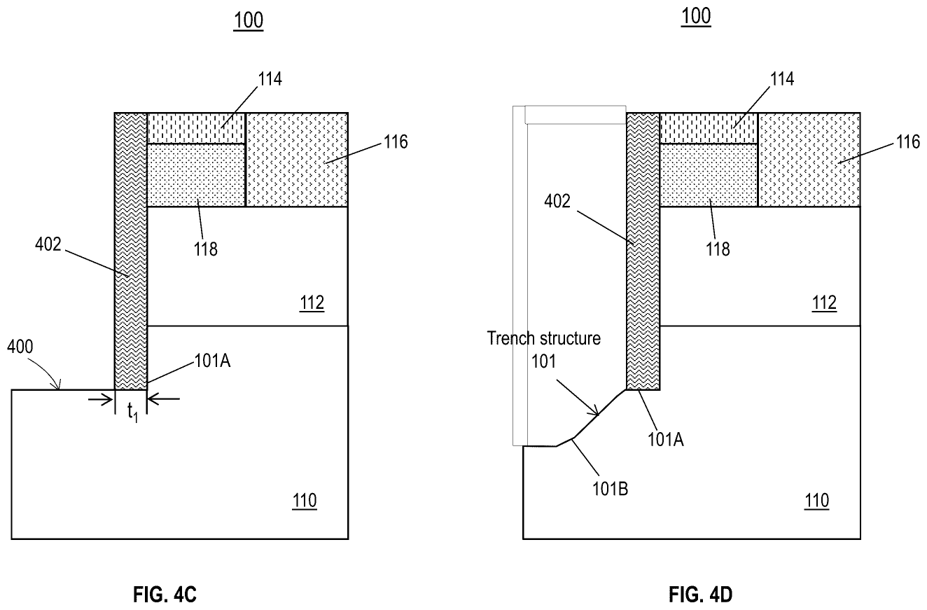

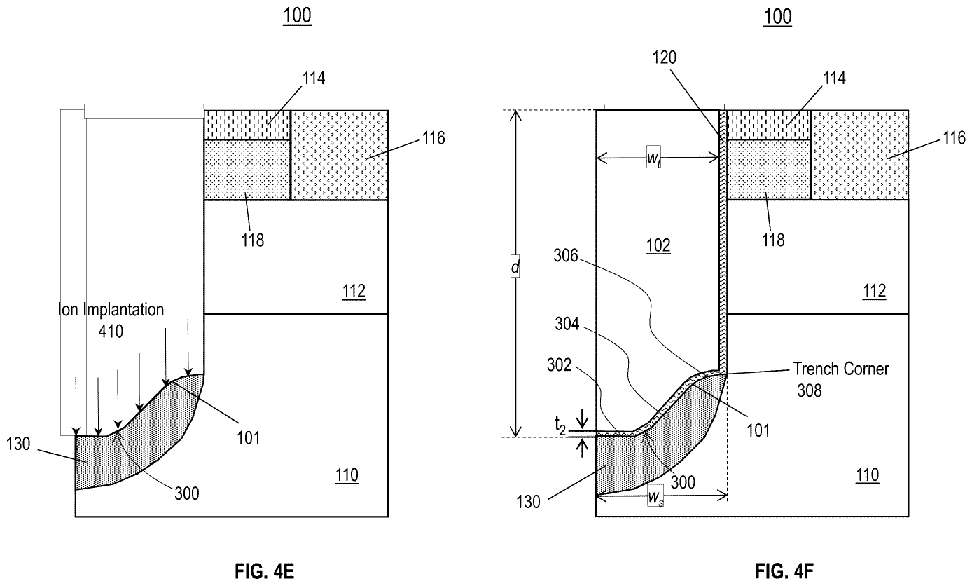

FIG. 4A to FIG. 4F illustrate a series of steps in a manufacturing process of the double sequential trench semiconductor structure 100, according to an embodiment of the present disclosure. Specifically, FIG. 4A to FIG. 4F illustrates the process of forming a double sequential trench Silicon Carbide MOSFET. Descriptions of FIG. 4A to FIG. 4F can reference components shown in FIG. 1 to FIG. 3.

FIG. 4A is a side view of the semiconductor structure 100 depicting forming a first trench structure 101A, according to an embodiment of the present disclosure. The process of forming the first trench structure 101A typically involves exposing a pattern on a photoresist layer, transferring the pattern to a hardmask layer (not shown) and then to the drift region 110 using lithography and reactive-ion etching (RIE) processing.

FIG. 4B is a side view of the semiconductor structure 100 depicting forming a first layer of oxide (hereinafter “first oxide”) 402, according to an embodiment of the present disclosure. The first oxide 402 can be formed to line the walls of the first trench structure 101A. The first oxide 402 can be formed by thermal oxidation of an oxide material. However, in some embodiments, the first oxide 402 can be formed by conformal deposition of the oxide material. The first oxide 402 can be, for example, high-quality oxide that has relatively superior properties compared to other oxides in terms of purity, stability, or specific functional characteristics. The first oxide 402 can be formed by oxides such as, for example, Silicon Dioxide (SiO₂). In an embodiment, a thickness t₁ of the first oxide 402 can vary between approximately 1 nm to approximately 0.2 μm.

FIG. 4C is a side view of the semiconductor structure 100 depicting removing a portion of the first oxide 402, according to an embodiment of the present disclosure. In this embodiment, a portion of the first oxide 402 located above a bottom region 400 of the first trench structure 101A can be removed from the semiconductor structure 100. Stated differently, horizontal portions of the first oxide 402, i.e., portions of the first oxide 402 parallel to the drift region 110 can be selectively removed from the semiconductor structure 100. Vertical portions of the first oxide 402, i.e., portions of the first oxide 402 perpendicular to the drift region 110, remain in the semiconductor structure 100 lining vertical sidewalls of the first trench structure 101A, as depicted in the figure. Various dry or wet etching techniques can be used to selectively removed portions of the first oxide 402 located above the bottom region 400 of the first trench structure 101A, ensuring that the vertical portions of the first oxide 402 are preserved.

It should be noted that the hardmask (not shown) used in the formation of the first trench structure 101A can be retained during deposition of the first oxide 402. The combination of the hardmask and the first oxide 402 can be used for the sequential trench etching.

FIG. 4D is a side view of the semiconductor structure 100 depicting forming a second trench structure 101B, according to an embodiment of the present disclosure. The process of forming the second trench structure 101B involves using an angled etching technique, such as Reactive Ion Etching (RIE), to achieve the desired trench angle. In some embodiments, a rounded etching process can alternatively be used to form the second trench structure 101B. As may be understood angled etching results in sharper profiles, while rounded etching leads to smoother, more rounded edges. The choice between the two techniques can depend on the specific requirements of the MOSFET being fabricated, including performance targets, reliability needs, and manufacturing considerations.

In this embodiment, the remaining vertical portion of the first oxide 402 serves as a protective hardmask during the formation of the second trench structure 101B. After the formation of the second trench structure 101B, the first oxide 402 can be removed from the semiconductor structure 100 using any suitable etching technique. Accordingly, once the first oxide 402 is removed, a length (L₃) of the portion of the trench structure 101 (i.e., upper section 306) that was previously covered by the first oxide 402 is equal to the thickness t₁ of the first oxide 402. Thus, the thickness t₁ of the remaining vertical portion of the first oxide 402 determines the length L₃ of the upper section 306 of the trench structure 101. More particularly, the length L₃ of the upper section 306, as depicted in FIG. 3, is derived from the thickness t₁ of the first oxide 402 during the etching process for the sequential trench formation.

For clarity, from this point forward, the first trench 101A and the second trench 101B will be collectively referred to as trench structure 101.

FIG. 4E is a side view of the semiconductor structure 100 depicting forming a third doped region or shield region 130, according to an embodiment of the present disclosure. In this embodiment, an ion implantation process 410 can be conducted on the bottom region 300 of the trench structure 101. Implantation of shield region 130 can include various techniques such as using a photomask or an implant mask to selectively block or allow the implantation of dopants of the second conductivity type (e.g., Aluminum) in the location of shield region 130 within drift region 110. By way of example, an ion implanter can be used for introducing ions of dopant material into the SiC lattice to create shield region 130 of the second conductivity type. Annealing can be performed to activate the dopants, repair damage to the substrate caused by the ion implantation, and to ensure that the dopants are properly incorporated into the lattice. In an embodiment, the shield region 130 can be formed with a dopant concentration varying between approximately 1×10¹⁵ cm⁻³ and 5×10¹⁷ cm⁻³.

FIG. 4F is a side view of the semiconductor structure 100 depicting the formation of oxide region 120 and gate 102, according to an embodiment of the present disclosure. After forming the shield region 130, the oxide region 120 is formed lining the walls of trench structure 101, in preparation for deposition of the gate 102. The oxide region 120 includes a gate insulating film for electrically separating the gate electrode or gate 102 from other active regions of the semiconductor structure 100. Similar to the first oxide 402, the oxide region 120 can be formed by thermal oxidation of an oxide material. However, in some embodiments, the oxide region 120 can be formed by conformal deposition of the oxide material. The oxide region 120 can be, for example, high-quality oxide that has relatively superior properties compared to other oxides in terms of purity, stability, or specific functional characteristics. The oxide region 120 can be formed by oxides such as, for example, Silicon Dioxide (SiO₂). In an embodiment, a thickness t₂ of the oxide region 120 can vary between approximately 1 nm to approximately 500 nm. To form gate 102, a conductive material, such as polysilicon, can be deposited within trench structure 101 on top of oxide region 120.

In the depicted embodiment, the trench structure 101 exhibits a varying horizontal width as it extends into the drift region 110 (e.g., in the x-direction) due to the varying inclination angles of the bottom region 300. In upper areas of the trench structure 101, a width wₜ of the trench structure 101 can vary between approximately 0.5 μm to approximately 2 μm. As can be observed, the width wₜ of trench structure 101 narrows towards the bottom region 300, specifically from the upper section 306 towards the bottom section 302. Additionally, a (vertical) depth of trench structure 101 into the drift region 110 (e.g., in the −y direction) can vary as a result of the stepped profile of trench structure 100. In an embodiment, a total depth d of the trench structure 101, from the widest upper section to the narrowest bottom section 302, can range from approximately 0.5 μm to approximately 10 μm, with a preferred range of approximately 0.5 μm to approximately 2 μm. It should be noted that a width wₛ of the shield region 130 does not exceed the width wₜ of the widest section of trench structure 101. Stated differently, the width wₛ of the shield region 130 remains within the width wₜ of the widest section of trench structure 101. Thus, the width wₛ of the shield region 130 is at least equal to the width wₜ of the widest section of trench structure 101.

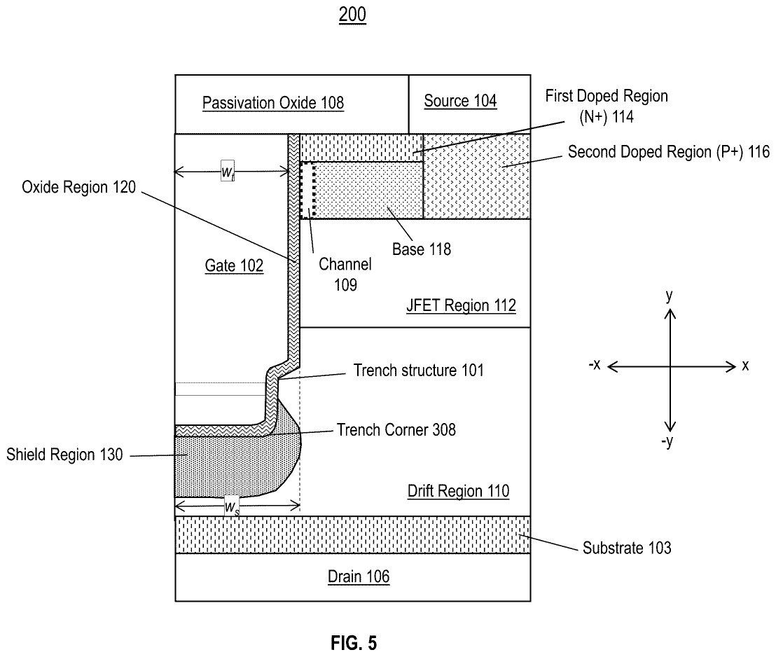

FIG. 5 illustrates a side view of a semiconductor structure 200, according to an embodiment of the present disclosure. Specifically, in this embodiment, FIG. 5 depicts another example of a portion of a double sequential trench SiC MOSFET. In this embodiment, the sloped section 304 of the trench structure 101 as depicted in FIG. 3 is oriented horizontally, resulting in an inclination angle α of 0 degrees. Thus, in this embodiment, the second trench structure 101B, illustrated in FIG. 4D, can be formed using an etching technique (i.e., etching is performed perpendicular to the substrate surface) that may be different from a tilted or angled etching process. The resulting flat or horizontal configuration of the lower portion of trench structure 101 still causes the shield region 130 to spread laterally (in the x-direction) increasing the doping concentration near the trench corner 308. It should be noted that the width wₛ of the shield region 130 does not extend beyond the width wₜ of the widest section of trench structure 101. Therefore, similar to semiconductor structure 100, the width wₛ of the shield region 130 remains within the width wₜ of the widest section of trench structure 101. So, the width wₛ of the shield region 130 is at least equal to the width wₜ of the widest section of trench structure 101.

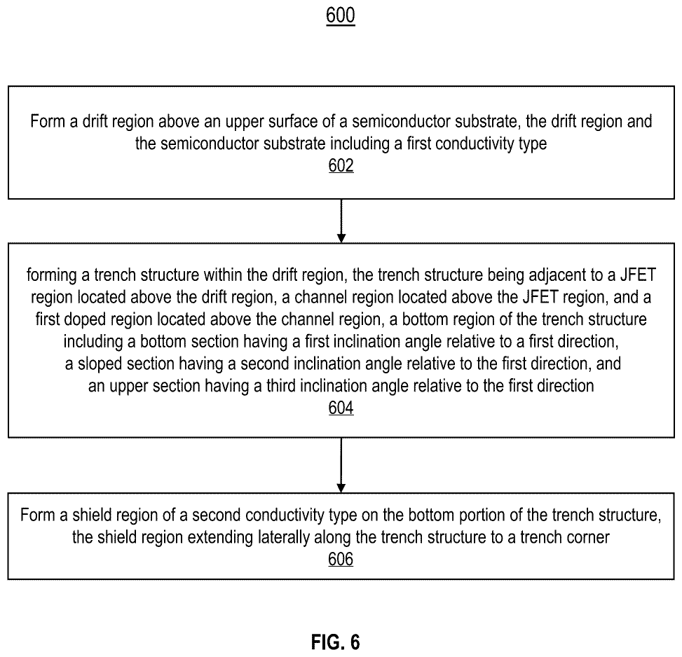

FIG. 6 depicts a flowchart 600 outlining operational steps for the fabrication of a semiconductor structure having a double sequential trench structure, according to an embodiment of the present disclosure.

The fabrication process starts at step 602 by forming a drift region above an upper surface of a semiconductor substrate, the drift region and the semiconductor substrate including a first conductivity type.

The process continues at step 604 by forming a trench structure within the drift region. The trench structure is adjacent to a JFET region located above the drift region, a channel region located above the JFET region and a first doped region located above the channel region. A bottom region of the trench structure is made of a bottom section having a first inclination angle relative to a first direction, a sloped section having a second inclination angle relative to the first direction, and an upper section having a third inclination angle relative to the first direction. The process of forming the trench structure (step 604) further includes forming a first trench structure within the drift region, forming a first oxide lining the first trench structure, removing a horizontal portion of the first oxide while a vertical portion of the first oxide remains along vertical sidewalls of the first trench structure, forming a second trench structure within the drift region with the second trench structure being adjacent to the first trench structure, and removing the first oxide. In an embodiment, the second trench structure can be formed by an angled etching process.

According to an embodiment, the bottom section and the upper section of the trench structure are substantially flat with the first inclination angle and the third inclination angle being approximately zero degrees relative to the first direction. In an embodiment, the sloped section has a tilted profile with the second inclination angle being less than 45 degrees and more than 0 degrees relative to the first direction. In another embodiment, the sloped section has a horizontal profile with the second inclination angle being equal to 0 degrees relative to the first direction. The first direction corresponds to an x-direction. The bottom section, sloped section, and upper section of the trench structure create a stepped profile.

After forming the trench structure at step 604, a shield region of a second conductivity type is formed, at step 606, on the bottom region of the trench structure. The shield region extends laterally along the trench structure to a trench corner. The shield region can be formed by implanting ion dopants of the second conductivity type on the bottom region of the trench structure. The ion implantation can be conducted until an impurity concentration of the shield region is more than 1×10¹⁵ cm⁻³ and less than 5×10¹⁷ cm⁻³. In an embodiment, a width of the shield region is at least equal to a width of a widest portion of the trench structure. In one or more embodiments, the width of the widest portion of the trench structure narrows towards the bottom region, with a narrowest portion corresponding to the bottom section of the trench structure.

According to an embodiment, additional steps of the fabrication process can include forming an oxide region within the trench structure with the oxide region lining sidewalls and the bottom region of the trench structure. A bottom surface of the oxide region is in contact with an upper surface of the shield region. After forming the oxide region, a gate electrode can be formed above the oxide region substantially filling the trench structure.

According to an embodiment, additional steps of the fabrication process can include forming a base region of the second conductivity type adjacent to the trench structure, the first doped region being disposed above the base region, forming a second doped region of the second conductivity type adjacent to the first doped region and the base region, forming a source electrode above the second doped region, the source electrode partially extending above the first doped region, forming a passivation oxide above the gate electrode and adjacent to the source electrode, the passivation oxide partially extending above the first doped region, and forming a drain electrode on a bottom surface of the semiconductor substrate.

### EXAMPLES

Example 1. A method of forming a semiconductor structure, comprising:
forming a drift region above an upper surface of a semiconductor substrate, the drift region and the semiconductor substrate including a first conductivity type;
forming a trench structure within the drift region, the trench structure being adjacent to a JFET region located above the drift region, a channel region located above the JFET region and a first doped region located above the channel region, wherein a bottom region of the trench structure includes:
   a bottom section having a first inclination angle relative to a first direction,
   a sloped section having a second inclination angle relative to the first direction, and
   an upper section having a third inclination angle relative to the first direction; and
forming a shield region of a second conductivity type on the bottom region of the trench structure, wherein the shield region extends laterally along the trench structure to a trench corner.

Example 2. The method according to Example 1, wherein forming the trench structure includes:
forming a first trench structure within the drift region;
forming a first oxide lining the first trench structure;
removing a horizontal portion of the first oxide, a vertical portion of the first oxide remaining along vertical sidewalls of the first trench structure;
forming a second trench structure within the drift region, the second trench structure being adjacent to the first trench structure; and
removing the first oxide.

Example 3. The method according to Example 2, wherein forming the second trench structure includes:
conducting an angled etching process.

Example 4. The method according to Example 1, wherein forming the shield region includes:
implanting ion dopants of the second conductivity type on the bottom region of the trench structure.

Example 5. The method according to Example 1, wherein an impurity concentration of the shield region is more than 1×10¹⁵ cm⁻³ and less than 5×10¹⁷ cm⁻³.

Example 6. The method according to Example 1, wherein the bottom section and the upper section are substantially flat with the first inclination angle and the third inclination angle being approximately zero degrees relative to the first direction.

Example 7. The method according to Example 1, wherein the sloped section has a tilted profile with the second inclination angle being less than 45 degrees and more than 0 degrees relative to the first direction.

Example 8. The method according to Example 1, wherein the sloped section has a horizontal profile with the second inclination angle being equal to 0 degrees relative to the first direction.

Example 9. The method according to Example 1, wherein the first direction corresponds to an x-direction.

Example 10. The method according to Example 1, wherein the trench structure has a stepped profile formed by the bottom section, sloped section, and upper section.

Example 11. The method according to Example 1, wherein a width of the shield region is at least equal to a width of a widest portion of the trench structure.

Example 12. The method according to Example 11, wherein the width narrows towards the bottom region of the trench structure, with a narrowest portion corresponding to the bottom section.

Example 13. The method according to Example 1, further comprising:
forming an oxide region within the trench structure, the oxide region lining the trench structure, a bottom surface of the oxide region being in contact with an upper surface of the shield region; and
forming a gate electrode above the oxide region.

Example 14. The method according to Examples 1 or 13, further comprising:
forming a base region of the second conductivity type adjacent to the trench structure, the first doped region being disposed above the base region;
forming a second doped region of the second conductivity type adjacent to the first doped region and the base region;
forming a source electrode above the second doped region, the source electrode partially extending above the first doped region;
forming a passivation oxide above the gate electrode and adjacent to the source electrode, the passivation oxide partially extending above the first doped region; and
forming a drain electrode on a bottom surface of the semiconductor substrate.

Example 15. A method of forming a semiconductor structure, comprising:
forming a drift region above an upper surface of a semiconductor substrate, the drift region and the semiconductor substrate including a first conductivity type;
forming a first trench structure within the drift region, the first trench structure including a horizontal profile;
forming a first oxide within the first structure, the first oxide conformally lining the first trench structure;
removing a horizontal portion of the first oxide, a vertical portion of the first oxide remaining along vertical sidewalls of the first trench structure;
forming a second trench structure within the drift region adjacent to the first trench structure, the second trench structure including a tilted profile, the first trench structure and the second trench structure include a double sequential trench structure;
removing the remaining vertical portion of the first oxide; and
forming a shield region of a second conductivity type, wherein the shield region extends laterally along the trench structure to a trench corner, a width of the shield region being at least equal to a width of a widest portion of the trench structure.

Example 16. The method according to Example 15, wherein forming the second trench structure includes:
conducting an angled etching process.

Example 17. The method according to Example 15, wherein forming the shield region includes:
implanting ion dopants of the second conductivity type on a bottom region of the trench structure.

Example 18. The method according to Example 15, wherein an impurity concentration of the shield region is more than 1×10¹⁵ cm⁻³ and less than 5×10¹⁷ cm⁻³.

Example 19. The method according to Example 15, wherein the double sequential trench structure features a stepped profile formed by a bottom section and an upper section without any tilting relative to a horizontal direction connected by a sloped section having an inclination angle that is less than 45 degrees and more than 0 degrees relative to the horizontal direction.

Example 20. The method according to Example 19, wherein the inclination angle of the sloped section is equal to 0 degrees relative to the horizontal direction.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type, the semiconductor structure including silicon carbide;
a drift layer of the first conductivity type located above the semiconductor substrate;
a channel layer of a second conductivity type opposite to the first conductivity type located above the drift layer;
a source region of the first conductivity type located above the channel layer;
a trench structure extending through the source region and the channel layer until a top portion of the drift layer;
a gate electrode located within the trench structure, the gate electrode being surrounded by a gate insulating film; and
a shield region of the second conductivity type covering a bottom of the trench structure such that the shield region extends laterally along the trench structure to a trench corner, wherein the bottom of the trench structure has a stepped shape.

2. The semiconductor structure according to claim 1, wherein the bottom of the trench structure includes a bottom section, a sloped section, and an upper section that provide the stepped shape.

3. The semiconductor structure according to claim 2, wherein the upper section is located between a sidewall of the trench structure and the sloped section, the upper section having a substantially flat profile.

4. The semiconductor structure according to claim 2, wherein a length of the upper section is more than 1 nm and less than 0.2 m.

5. The semiconductor structure according to claim 2, wherein the sloped section is angled such that a width of the trench structure narrows toward the bottom section.

6. The semiconductor structure according to claim 2, wherein an inclination angle of the sloped section is more than 0 degree and less than 45 degrees.

7. The semiconductor structure according to claim 2, wherein a distance between the upper section and the bottom section is more than 1 nm and less than 0.2 m.

8. The semiconductor structure according to claim 1, wherein the shield region is directly connected to the bottom of the trench structure.

9. The semiconductor structure according to claim 1, wherein an impurity concentration of the shield region is less than an impurity concentration of the channel layer.

10. The semiconductor structure according to claim 1, wherein an impurity concentration of the shield region is more than 1×10¹⁵ cm⁻³ and less than 5×10¹⁷ cm⁻³.

11. A semiconductor structure comprising:
a drift region disposed above an upper surface of a semiconductor substrate, the drift region and the semiconductor substrate including a first conductivity type;
a trench structure within the drift region, the trench structure being adjacent to a JFET region located above the drift region, a channel region located above the JFET region and a first doped region located above the channel region, wherein a bottom region of the trench structure includes:
a bottom section having a first inclination angle relative to a first direction,
a sloped section having a second inclination angle relative to the first direction, and
an upper section having a third inclination angle relative to the first direction; and
a shield region of a second conductivity type disposed on the bottom region of the trench structure, wherein the shield region extends laterally along the trench structure to a trench corner.

12. The semiconductor structure according to claim 11, wherein an impurity concentration of the shield region is more than 1×10¹⁵ cm⁻³ and less than 5×10¹⁷ cm⁻³.

13. The semiconductor structure to claim 11, wherein:
the bottom section and the upper section are substantially flat with the first inclination angle and the third inclination angle being approximately zero degrees relative to the first direction,
the sloped section has a tilted profile with the second inclination angle being less than 45 degrees and more than 0 degrees relative to the first direction,
the trench structure has a stepped profile formed by the bottom section, the sloped section, and the upper section, and
the first direction corresponds to an x-direction.

14. The semiconductor structure according to claim 11, wherein the sloped section has a horizontal profile with the second inclination angle being equal to 0 degrees relative to the first direction.

15. The semiconductor structure according to claim 11, wherein a width of the shield region is at least equal to a width of a widest portion of the trench structure.

16. The semiconductor structure according to claim 15, wherein the width of the shield region narrows towards the bottom region of the trench structure, with a narrowest portion corresponding to the bottom section.

17. The semiconductor structure according to claim 11, further comprising:
an oxide region within the trench structure, the oxide region lining the trench structure, a bottom surface of the oxide region being in contact with an upper surface of the shield region; and
a gate electrode above the oxide region.

18. The semiconductor structure according to claim 11, further comprising:
a base region of the second conductivity type adjacent to the trench structure, the first doped region being disposed above the base region;
a second doped region of the second conductivity type adjacent to the first doped region and the base region;
a source electrode located above the second doped region, the source electrode partially extending above the first doped region;
a passivation oxide located above a gate electrode located within the trench structure and adjacent to the source electrode, the passivation oxide partially extending above the first doped region; and
a drain electrode located on a bottom surface of the semiconductor substrate.

19. A semiconductor structure comprising:
a drift region located above an upper surface of a semiconductor substrate, the drift region and the semiconductor substrate including a first conductivity type;
a first trench structure within the drift region, the first trench structure including a horizontal profile;
a second trench structure within the drift region adjacent to the first trench structure, the second trench structure including a tilted profile, the first trench structure and the second trench structure include a double sequential trench structure; and
a shield region of a second conductivity type, wherein the shield region extends laterally along the double sequential trench structure to a trench corner, a width of the shield region being at least equal to a width of a widest portion of the double sequential trench structure.

20. The semiconductor structure according to claim 19, wherein the double sequential trench structure features a stepped profile formed by a bottom section and an upper section without any tilting relative to a horizontal direction connected by a sloped section having an inclination angle that is less than 45 degrees and more than 0 degrees relative to the horizontal direction.
